(19) United States
(12) Patent Application Publication
(10) Pub. No.: US 2025/0059681 A1
(43) Pub. Date: Feb. 20, 2025

(54) METHOD OF PROCESSING CARBON-CONTAINED MONOCRYSTALLINE SUBSTRATE

(71) Applicant: DISCO CORPORATION, Tokyo (JP)

(72) Inventors: Naoki MURAZAWA, Tokyo (JP); Hiroshi MORIKAZU, Tokyo (JP); Tsubasa HIROSE, Tokyo (JP)

(21) Appl. No.: 18/794,112

(22) Filed: Aug. 5, 2024

(30) Foreign Application Priority Data
Aug. 17, 2023 (JP) 2023-133103

(51) Int. Cl. C30B 33/02; C30B 29/04; C30B 29/36

(52) U.S. Cl. CPC C30B 33/02; C30B 29/04; C30B 29/36

(57) ABSTRACT

A method of processing a carbon-contained monocrystalline substrate that contains carbon as a main component of a single crystal includes a processed-groove forming step of forming a processed groove in the substrate by applying a first laser beam having a wavelength absorbable by the substrate to the substrate along a projected dicing line established on one surface of the substrate, and a heating step of causing products that contain carbon, that have a structure different from that of a material of the substrate, that are produced in the processed-groove forming step, and that are positioned at least within the processed groove to react with oxygen to vaporize the products, thereby removing the products, by applying a second laser beam having a wavelength transmittable through the substrate and absorbable by the products to the substrate along the processed groove.

### BACKGROUND OF THE INVENTION

### Field of the Invention

The present invention relates to a method of processing a carbon-contained monocrystalline substrate that contains carbon as a main component of a single crystal.

### Description of the Related Art

In recent years, attention has been paid to efforts to incorporate in semiconductor devices diamond substrates that are better in physical properties including withstand voltage and thermal conductivity than monocrystalline silicon substrates (see, for example, Japanese Patent Laid-open No. 2015-57824).

For fabricating semiconductor device chips by dividing ordinary semiconductor substrates such as monocrystalline silicon substrates, there has been used a cutting apparatus having a spindle with a cutting blade mounted on its distal end, for example,

However, when a semiconductor substrate of high Mohs hardness, such as a diamond substrate, is cut on such a cutting apparatus, the cutting blade tends to be worn severely, posing some problems. For example, (i) as the cutting of the substrate goes on, the substrate has its cut surface changed in shape due to the severely worn cutting blade. (ii) Since the cutting blade needs to be replaced frequently, the cost involved in the cutting process goes high.

There has been proposed, as a solution to the above problems, a method of dividing a semiconductor substrate having relatively high Mohs hardness by, rather than using a cutting blade, applying a laser beam having a wavelength absorbable by the semiconductor substrate to the semiconductor substrate along projected dicing lines established thereon, and forming laser-processed grooves in the semiconductor substrate by way of ablation (see, for example, Japanese Patent Laid-open No. H10-305420).

When a laser beam is applied to a diamond substrate, however, part of the diamond is carbonized to produce graphite. Products of graphite are deposited on the bottom and side surfaces of laser-processed grooves formed in the substrate along projected dicing lines, possibly varying electric characteristics of semiconductor devices on the substrate. Consequently, the products of graphite may possibly cause faults of semiconductor device chips manufactured from the substrate. Similar problems may occur when a laser beam is applied to a silicon carbide substrate that contains carbon as a main component of a single crystal.

### SUMMARY OF THE INVENTION

The present invention has been made in view of the problems described above. It is an object of the present invention to provide a method of processing a carbon-contained monocrystalline substrate that contains carbon as a main component of a single crystal, such as a diamond substrate or a silicon carbide substrate, to improve the yield of semiconductor device chips manufactured from the substrate by removing at least part of products produced when a laser beam is applied to the substrate.

In accordance with an aspect of the present invention, there is provided a method of processing a carbon-contained monocrystalline substrate that contains carbon as a main component of a single crystal, including a processed-groove forming step of forming a processed groove in the carbon-contained monocrystalline substrate by applying a first laser beam having a wavelength absorbable by the carbon-contained monocrystalline substrate to the carbon-contained monocrystalline substrate along a projected dicing line established on one surface of the carbon-contained monocrystalline substrate, and a heating step of causing products that contain carbon, that have a structure different from that of a material of the carbon-contained monocrystalline substrate, that are produced in the processed-groove forming step, and that are positioned at least within the processed groove to react with oxygen to vaporize the products, thereby removing the products, by applying a second laser beam having a wavelength transmittable through the carbon-contained monocrystalline substrate and absorbable by the products to the carbon-contained monocrystalline substrate along the processed groove.

Preferably, the processed-groove forming step includes severing the carbon-contained monocrystalline substrate by forming the processed groove that extends through the carbon-contained monocrystalline substrate from the one surface thereof to another surface thereof that is opposite the one surface.

Preferably, alternatively, the processed-groove forming step includes forming the processed grove that has a depth from the one surface of the carbon-contained monocrystalline substrate to a point therein that is short of another surface thereof that is opposite the one surface, without severing the carbon-contained monocrystalline substrate, the method further including, before or after the heating step, a rupturing step of rupturing the carbon-contained monocrystalline substrate by applying an external force to a residual region of the carbon-contained monocrystalline substrate that underlies the processed groove in a thicknesswise direction of the carbon-contained monocrystalline substrate.

In accordance with another aspect of the present invention, there is provided a method of processing a carbon-contained monocrystalline substrate that contains carbon as a main component of a single crystal, including a laser beam applying step of applying a pulsed first laser beam having a wavelength transmittable through the carbon-contained monocrystalline substrate to the carbon-contained monocrystalline substrate along a projected dicing line established thereon, thereby forming a fragile region that is lower in mechanical strength than a non-irradiated region of the carbon-contained monocrystalline substrate to which the pulsed first laser beam is not applied, within the carbon-contained monocrystalline substrate, a dividing step of, after the laser beam applying step, dividing the carbon-contained monocrystalline substrate along the projected dicing line by applying an external force to the carbon-contained monocrystalline substrate, and a heating step of, after the dividing step, causing products that contain carbon, that have a structure different from that of a material of the carbon-contained monocrystalline substrate, and that are produced in the laser beam applying step to react with oxygen to vaporize the products, thereby removing the products, by applying a second laser beam having a wavelength transmittable through the carbon-contained monocrystalline substrate and absorbable by the products to at least severance surfaces of the carbon-contained monocrystalline substrate that have been exposed in the dividing step.

Preferably, the wavelength of the second laser beam applied to the carbon-contained monocrystalline substrate in the heating step is in a range of 9.0 μm to 11.0 μm.

Preferably, the carbon-contained monocrystalline substrate is a diamond substrate.

Preferably, the carbon-contained monocrystalline substrate is a silicon carbide substrate.

Preferably, the products contain graphite or amorphous carbon.

In the methods of processing a carbon-contained monocrystalline substrate according to the aspects of the present invention, the second laser beam whose wavelength is absorbable by the products produced by applying the first laser beam to the carbon-contained monocrystalline substrate is applied to the products, causing the products to react with oxygen to vaporize and remove the products. Therefore, the yield of the semiconductor device chips is rendered higher than if the products were not removed by the second laser beam.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a flowchart of a processing sequence of a method of processing a carbon-contained monocrystalline substrate, hereinafter also referred to as a substrate processing method, according to a first embodiment of the present invention;

FIG. 2 is a perspective view of a workpiece unit;

FIG. 3A is a fragmentary side elevational view, partly in cross section, illustrating a manner in which a processed-groove forming step of the substrate processing method according to the first embodiment is carried out;

FIG. 3B is a fragmentary side elevational view, partly in cross section, illustrating dividing grooves formed in the carbon-contained monocrystalline substrate according to the first embodiment;

FIGS. 4A and 4B are fragmentary side elevational views, partly in cross section, illustrating a manner in which a heating step of the substrate processing method according to the first embodiment is carried out;

FIG. 5A is a flowchart of a processing sequence of a substrate processing method according to a second embodiment of the present invention;

FIG. 5B is a flowchart of a processing sequence of a modification of the substrate processing method according to the second embodiment;

FIG. 6A is a fragmentary side elevational view, partly in cross section, illustrating a manner in which a processed-groove forming step of the substrate processing method according to the second embodiment is carried out;

FIG. 6B is a fragmentary side elevational view, partly in cross section, illustrating half-cut grooves formed in the carbon-contained monocrystalline substrate according to the second embodiment;

FIG. 7A is a side elevational view, partly in cross section, illustrating an expanding apparatus;

FIG. 7B is a side elevational view, partly in cross section, illustrating a manner in which a rupturing step according to the second embodiment is carried out by the expanding apparatus;

FIG. 8A is a fragmentary side elevational view, partly in cross section, illustrating a breaking apparatus;

FIG. 8B is a fragmentary side elevational view, partly in cross section, illustrating a manner in which a modification of the rupturing step is carried out by the breaking apparatus;

FIG. 9 is a flowchart of a processing sequence of a substrate processing method according to a third embodiment of the present invention;

FIG. 10 is a side elevational view, partly in cross section, illustrating a manner in which a laser beam applying step of the substrate processing method according to the third embodiment is carried out;

FIG. 11 is a fragmentary side elevational view of a carbon-contained monocrystalline substrate after a dividing step of the substrate processing method according to the third embodiment;

FIG. 12 is a side elevational view, partly in cross section, illustrating a manner in which a heating step of the substrate processing method according to the third embodiment is carried out;

FIG. 13 is a side elevational view, partly in cross section, illustrating a manner in which a laser beam applying step of a substrate processing method according to a fourth embodiment of the present invention is carried out;

FIG. 14A is a perspective view illustrating a structure of a shield tunnel; and

FIG. 14B is a fragmentary cross-sectional view of a carbon-contained monocrystalline substrate having a plurality of shield tunnels.

### DETAILED DESCRIPTION OF THE PREFERRED EMBODIMENTS

### First Embodiment

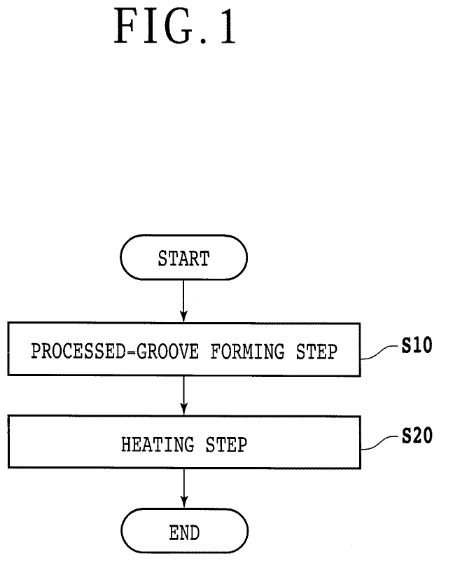

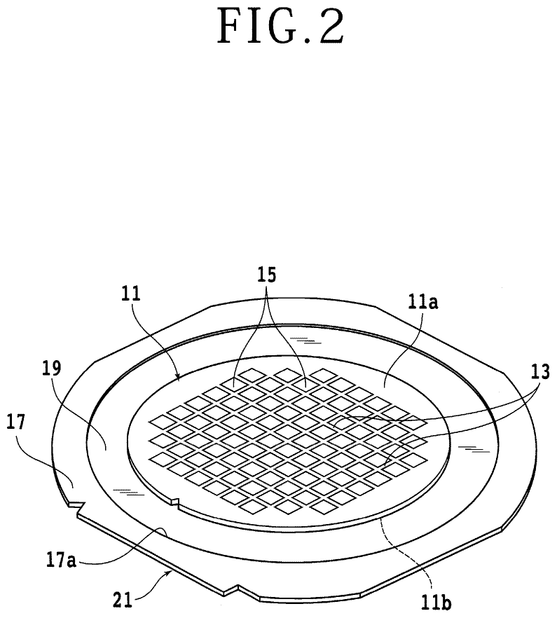

A method of processing a carbon-contained monocrystalline substrate according to a first embodiment of the present invention will be described below with reference to FIGS. 1 through 4B. FIG. 1 is a flowchart of a processing sequence of the substrate processing method of processing a carbon-contained monocrystalline substrate 11 (see FIG. 2) according to the first embodiment. According to the first embodiment, the carbon-contained monocrystalline substrate 11 is processed successively in a processed-groove forming step S10 and a heating step S20 of the substrate processing method. FIG. 2 illustrates in perspective a workpiece unit 21 including the carbon-contained monocrystalline substrate 11. According to the first embodiment, the carbon-contained monocrystalline substrate 11 is a diamond substrate. Generally, the diamond substrate is made of synthetic diamond, though it may be made of natural diamond.

The diamond substrate that is made of synthetic diamond may be fabricated by any of various fabrication methods including vapor phase synthesis such as chemical vapor deposition (CVD) and high-temperature high-pressure synthesis. The diamond substrate is a cubic monocrystalline substrate containing carbon (C) as a main component and may contain an n-type impurity such as phosphorus (P), a p-type impurity such as boron (B), or other impurities. The diamond substrate is of a disk shape having a thickness of 500 μm and a diameter of 5 mm, for example. However, the diamond substrate is not limited to any particular thicknesses, diameters, and shapes. For example, the diamond substrate may be shaped as a rectangular plate.

The carbon-contained monocrystalline substrate 11 may alternatively be a silicon carbide substrate. The silicon carbide substrate may be fabricated by any of various fabrication methods. The silicon carbide substrate is made of silicon (Si) and carbon (C) as main components and generally is a hexagonal monocrystalline substrate. The silicon carbide substrate may contain an n-type impurity such as phosphorus (P) or nitrogen (N), a p-type impurity such as aluminum (Al) or boron (B), or other impurities. The silicon carbide substrate is of a disk shape having a thickness of 350 μm and a diameter of 150 mm, for example. However, the silicon carbide substrate is not limited to any particular thicknesses, diameters, and shapes. For example, the silicon carbide substrate may be shaped as a rectangular plate. Moreover, the carbon-contained monocrystalline substrate 11 may be a monocrystalline substrate of other materials as long as it contains carbon (C) as a main component.

As illustrated in FIG. 2, the carbon-contained monocrystalline substrate 11 according to the present embodiment has a disk shape. The carbon-contained monocrystalline substrate 11 has a face side, i.e., one surface, 11a with a grid of projected dicing lines 13 established thereon. The projected dicing lines 13 demarcate a plurality of areas on the face side 11a with devices 15 such as light-emitting diodes (LEDs) or integrated circuits (ICs) constructed in the respective areas.

The carbon-contained monocrystalline substrate 11 is secured to an annular frame 17 of metal by a dicing tape 19 of resin. Specifically, with the carbon-contained monocrystalline substrate 11 disposed in an opening 17a in the annular frame 17, the dicing tape 19 is affixed to a reverse side, i.e., another surface, 11b, opposite the face side 11a, of the carbon-contained monocrystalline substrate 11 and a surface, i.e., a lower surface in FIG. 2, of the annular frame 17. In this manner, the carbon-contained monocrystalline substrate 11 is secured to the annular frame 17 by the dicing tape 19.

The dicing tape 19 is a thin sheet of film that is flexible. The dicing tape 19 is plastically deformable by being stretched radially outwardly and has a laminated structure including a base layer and an adhesive layer, i.e., a glue layer, for example. The base layer is made of resin such as polyolefin (PO). The adhesive layer that is made of adhesive resin such as ultraviolet (UV)-curable resin is deposited wholly or partly on one surface of the base layer.

However, the dicing tape 19 is not structurally limited to a laminated structure including a base layer and an adhesive layer. The dicing tape 19 may be free of an adhesive layer and may include only a base layer. The base layer may be made of thermoplastic resin such as polyolefin, for example. By applying the dicing tape 19 that includes no adhesive layer to the carbon-contained monocrystalline substrate 11 by way of thermocompression bonding, the carbon-contained monocrystalline substrate 11 can be secured to the dicing tape 19 without using an adhesive layer. The dicing tape 19 free of an adhesive layer is advantageous in that, after the dicing tape 19 is peeled off from the carbon-contained monocrystalline substrate 11, no adhesive layer residuals remain on the carbon-contained monocrystalline substrate 11. The area of the dicing tape 19 that is held in contact with the annular frame 17 may have or may not have an adhesive layer.

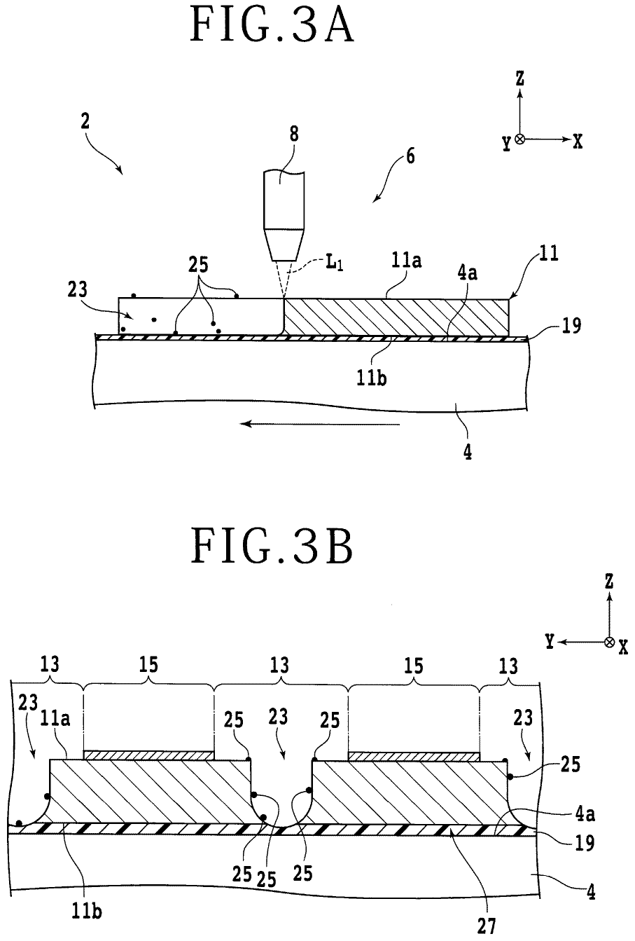

According to the present embodiment, the processed-groove forming step S10 and the heating step S20 are performed on the carbon-contained monocrystalline substrate 11 that is included in the workpiece unit 21 where the carbon-contained monocrystalline substrate 11 is supported on the annular frame 17 by the dicing tape 19. In the processed-groove forming step S10, a laser processing apparatus 2 (see FIG. 3A) is used. The laser processing apparatus 2 has a disk-shaped chuck table 4 for holding the workpiece unit 21 under suction thereon. As illustrated in FIG. 3A, the chuck table 4 has a disk-shaped frame.

The frame has a disk-shaped cavity defined centrally in a top portion thereof, and a disk-shaped porous plate having an outer diameter that is substantially the same as the inner diameter of the cavity is fixed in the cavity. The frame and the porous plate have respective upper surfaces that lie substantially flush with each other, making up a holding surface 4a for holding under suction thereon the carbon-contained monocrystalline substrate 11 with the dicing tape 19 interposed therebetween.

The chuck table 4 is movable along an X-axis including a processing-feed direction by a moving mechanism including a first ball screw, not depicted, and is also movable along a Y-axis including an indexing-feed direction by a moving mechanism including a second ball screw, not depicted. The chuck table 4 is rotatable about a predetermined rotational axis substantially parallel to a Z-axis including upward and downward directions by an electric motor, not depicted. The X-axis, the Y-axis, and the Z-axis referred to herein extend perpendicularly to each other.

A plurality of clamp units, not depicted, that can be opened and closed by respective air actuators, not depicted, are disposed around the chuck table 4. When the clamp units are closed, they grip the annular frame 17 of the workpiece unit 21 that is held under suction on the holding surface 4a.

The laser processing apparatus 2 also includes a laser beam applying unit 6 that includes a beam condenser 8 disposed above the holding surface 4a. The laser beam applying unit 6 also includes a laser oscillator, not depicted, for emitting a laser beam Li, i.e., a first laser beam, as pulses. Though the laser beam Li is of a pulsed wave, it may alternatively be of a continuous wave.

The laser oscillator includes a laser medium, e.g., a Yb: YAG crystal, not depicted, and an exciting light source, not depicted, such as a lamp for applying exciting light to the laser medium. In the case where the laser beam Li is of a pulsed wave, the laser oscillator further includes a Q switch, not depicted, for controlling the timing of emission of the laser beam L₁, for example. Alternatively, the laser oscillator may include, instead of the Q switch, an electro-optic modulator (EOM) that is controlled by an electric signal to convert a continuous wave applied to the electro-optic modulator into a pulsed wave. Further alternatively, other means may be used to control the laser oscillator to emit a pulsed wave.

The laser beam Li has a wavelength, e.g., 1030 nm, absorbable by the carbon-contained monocrystalline substrate 11. The beam condenser 8 includes a mirror and a condensing lens, both not depicted, for example. The laser beam Li is applied from the beam condenser 8 to the holding surface 4a substantially perpendicularly thereto. A microscope camera unit, not depicted, that is used to specify orientations, positions, and the like of the projected dicing lines 13 is disposed in the vicinity of the beam condenser 8. The microscope camera unit and the laser beam applying unit 6 are movable along the Z-axis by a ball-screw-type Z-axis moving mechanism, not depicted.

The processed-groove forming step S10 will be described in detail below. FIG. 3A illustrates in fragmentary side elevation, partly in cross section, a manner in which the processed-groove forming step S10 is carried out. In FIG. 3A, the devices 15 on the carbon-contained monocrystalline substrate 11 are omitted from illustration for illustrative purposes. In the processed-groove forming step S10, the holding surface 4a holds under suction the carbon-contained monocrystalline substrate 11 thereon. Thereafter, the orientation of the chuck table 4 is adjusted to make one of the projected dicing lines 13 substantially parallel to the X-axis on the basis of an image captured by the microscope camera unit.

Then, while a focused spot of the laser beam Li is being kept at a height that is substantially the same as the height of the face side 11a of the carbon-contained monocrystalline substrate 11, the beam condenser 8 and the chuck table 4 are moved relatively to each other along the X-axis. For example, the beam condenser 8 is held at rest, and the chuck table 4 is moved along the X-axis at a predetermined processing-feed speed. In this manner, the laser beam Li emitted from the beam condenser 8 is applied to the carbon-contained monocrystalline substrate 11 along the projected dicing line 13, forming a dividing groove, i.e., a processed groove, 23 in the carbon-contained monocrystalline substrate 11 along the projected dicing line 13 by way of ablation.

An example of processing conditions in the processed-groove forming step S10 is given below. The example represents processing conditions for processing a diamond substrate having a thickness of 500 μm and a diameter of 5 mm as the carbon-contained monocrystalline substrate 11.
Laser beam wavelength: 1030 nm
Average power output: 80 W
Repetitive frequency: 2000 kHz
Processing-feed speed: 100 mm/s
Number of passes: 90

The number of passes signifies the number of times that a focused spot of a laser beam, e.g., the laser beam L₁, is moved from an end of a projected dicing line 13 to the other end thereof. If the number of passes is 2 or more, then the focused spot of the laser beam L₁ may be brought closer stepwise from the face side 11a to the reverse side 11b depending on the number of passes. In other words, the focused spot of the laser beam L₁ may be closest to the face side 11a on the first of the passes and may be closest to the reverse side 11b on the last of the passes.

The dividing groove 23 formed in the processed-groove forming step S10 according to the present embodiment is what is generally called a “fully cut groove” that extends from the face side 11a of the carbon-contained monocrystalline substrate 11 to the reverse side 11b thereof that is opposite the face side 11a. In other words, the dividing groove 23 severs the carbon-contained monocrystalline substrate 11 along the projected dicing line 13.

After the dividing groove 23 has been formed in the carbon-contained monocrystalline substrate 11 along the projected dicing line 13, the beam condenser 8 and the chuck table 4 are moved relatively to each other along the Y-axis by a predetermined index distance. Then, the laser beam L₁ is applied to the carbon-contained monocrystalline substrate 11 along a next projected dicing line 13 that is positioned adjacent along the Y-axis to the projected dicing line 13 along which the dividing groove 23 has previously been formed, forming another dividing groove 23 in the carbon-contained monocrystalline substrate 11 along the next projected dicing line 13.

Thereafter, the dividing groove 23 is formed in the carbon-contained monocrystalline substrate 11 along all of the projected dicing lines 13 that extend along the X-axis. Then, the chuck table 4 is turned through approximately 90 degrees about the rotational axis thereof. Thereafter, the dividing grooves 23 are similarly formed in the carbon-contained monocrystalline substrate 11 along all of the projected dicing lines 13 that extend along the X-axis. In this manner, the carbon-contained monocrystalline substrate 11 is divided by the dividing grooves 23 formed therein along all of the projected dicing lines 13 into a plurality of semiconductor device chips 27 (see FIG. 3B).

In the processed-groove forming step S10, the carbon of the carbon-contained monocrystalline substrate 11 is carbonized, producing products 25 that have a crystal structure different from that of the material of the carbon-contained monocrystalline substrate 11 and that contain carbon (C). The products 25 are made of a non-diamond material, i.e., an allotrope of carbon other than diamond and may be made of graphite, for example. However, the material of the products 25 is not limited to graphite and may contain amorphous carbon.

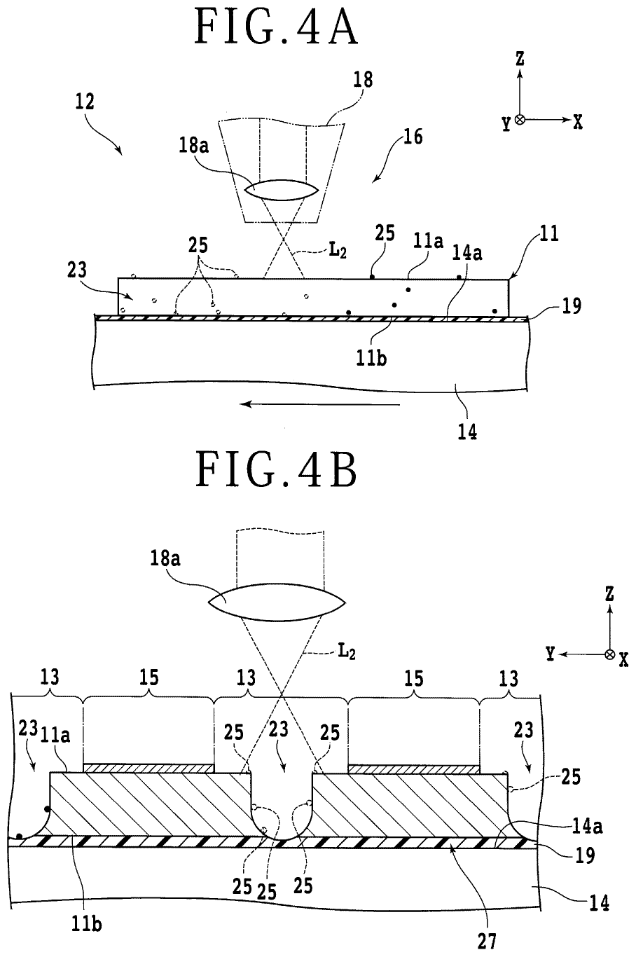

FIG. 3B illustrates the dividing grooves 23 formed in the carbon-contained monocrystalline substrate 11, in a cross section taken along a plane extending through the carbon-contained monocrystalline substrate 11 across longitudinal directions of the dividing grooves 23. The products 25 that are particulate in nature are positioned within the dividing grooves 23, i.e., on bottom and side surfaces thereof, and on opening edges of the dividing grooves 23. The products 25 may possibly give rise to faults of the semiconductor device chips 27. According to the present embodiment, after the processed-groove forming step S10, the products 25 are removed from the carbon-contained monocrystalline substrate 11 by a laser processing apparatus 12 (see FIG. 4A) in the heating step S20.

The laser processing apparatus 12 includes a chuck table 14 that is essentially identical in structure to the chuck table 4 described above. The chuck table 14 has a holding surface 14a and is movable along the X-axis and the Y-axis by two moving mechanisms having respective ball screws, not depicted. The chuck table 14 is rotatable about a predetermined rotational axis substantially parallel to the Z-axis by an electric motor, not depicted. A plurality of clamp units, not depicted, that can be opened and closed by respective air actuators, not depicted, are disposed around the chuck table 14.

The laser processing apparatus 12 also includes a laser beam applying unit 16 that includes a beam condenser 18 disposed above the holding surface 14a. The beam condenser 18 includes a condensing lens 18a. The laser beam applying unit 16 according to the present embodiment is what is generally called a carbon dioxide laser and includes a laser oscillator, not depicted, for emitting a laser beam L₂, i.e., a second laser beam.

The laser oscillator includes a discharge tube, not depicted, functioning as an optical resonator. The discharge tube is filled with a carbon dioxide gas. A total reflection mirror, not depicted, of high reflectivity is disposed at one end of the discharge tube whereas a transflective mirror is disposed at the opposite end of the discharge tube. The discharge tube also includes a pair of electrode plates between which a high-frequency voltage is applicable. When the high-frequency voltage is applied between the electrode plates, an electric discharge occurs between the electrode plates, causing the carbon dioxide gas in the discharge tube to turn into a plasma that emits a laser beam L₂ out of the discharge tube through the transflective mirror. In a case where the laser beam L₂ is of a pulsed wave, i.e., is emitted as pulses, the laser oscillator also includes a Q switch, not depicted, for controlling the timing of emission of the laser beam L₂.

The laser beam L₂ has a wavelength that is transmittable through the carbon-contained monocrystalline substrate 11 but is absorbable by the products 25. The wavelength of the laser beam L₂ is in a range of 9.0 μm to 11.0 μm, for example. According to the present embodiment, since the laser beam applying unit 16 uses a carbon dioxide laser, the wavelength of the laser beam L₂ is 9.4 μm or 10.6 μm. Though the laser beam L₂ according to the present embodiment is of a pulsed wave, it may alternatively be of a continuous wave. In any case, the laser beam L₂ is applied from the beam condenser 18 to the holding surface 14a substantially perpendicularly thereto.

A microscope camera unit, not depicted, is disposed in the vicinity of the beam condenser 18. The microscope camera unit and the laser beam applying unit 16 are movable along the Z-axis by a ball-screw-type Z-axis moving mechanism, not depicted.

The heating step S20 will be described in detail below. FIGS. 4A and 4B illustrate in fragmentary side elevation, partly in cross section, a manner in which the heating step S20 is carried out. In FIG. 4A, the devices 15 on the carbon-contained monocrystalline substrate 11 are omitted from illustration for illustrative purposes. In the heating step S20, the holding surface 14a holds under suction the carbon-contained monocrystalline substrate 11 thereon. Thereafter, the orientation of the chuck table 14 is adjusted to make one of the projected dicing lines 13 substantially parallel to the X-axis on the basis of an image captured by the microscope camera unit.

Then, while a focused spot of the laser beam L₂ is being kept at a height that is different from the height of the face side 11a of the carbon-contained monocrystalline substrate 11, i.e., while the laser beam L₂ is being defocused off the face side 11a, the beam condenser 18 and the chuck table 14 are moved relatively to each other along the X-axis. For example, the beam condenser 18 is held at rest, and the chuck table 14 is moved along the X-axis at a predetermined processing-feed speed.

In this manner, the laser beam L₂ emitted from the beam condenser 18 is applied to the carbon-contained monocrystalline substrate 11 along one dividing groove 23, causing the products 25 to react with an oxygen gas (O₂) to vaporize the products 25. Specifically, the chuck table 14 is placed in air at normal temperature and under normal pressure or in a space supplied with an oxygen gas as an atmospheric gas at a predetermined flow rate, and the laser beam L₂ is applied to the carbon-contained monocrystalline substrate 11 along the dividing groove 23, vaporizing the products 25 by causing them to react with the oxygen gas.

Therefore, the products 25 are removed from the inside of the dividing groove 23 and from the opening edge thereof, i.e., from at least the inside of the dividing groove 23. Since the laser beam L₂ is defocused off the face side 11a, the laser beam L₂ can be applied to areas in the vicinity of the opening edge of the dividing groove 23 in addition to the inside of the dividing groove 23, assisting in efficiently removing the products 25.

Examples of processing conditions in the heating step S20 in cases where the laser beam L₂ is of a pulsed wave and of a continuous wave are given below. The examples represent processing conditions for processing a diamond substrate having a thickness of 500 μm and a diameter of 5 mm as the carbon-contained monocrystalline substrate 11.

In the case where the laser beam L₂ is of a pulsed wave:
Laser beam wavelength: 9.4 μm or 10.6 μm
Average power output: 100 W
Repetitive frequency: 10 kHz
Processing-feed speed: 100 mm/s
Number of passes: 1 or more
   In the case where the laser beam L₂ is of a continuous wave:
Laser beam wavelength: 9.4 μm or 10.6 μm
Power output: 100 W
Processing-feed speed: 100 mm/s
Number of passes: 1 or more

After the laser beam L₂ has been applied to the carbon-contained monocrystalline substrate 11 along the dividing groove 23, the beam condenser 18 and the chuck table 14 are moved relatively to each other along the Y-axis by a predetermined index distance. Then, the laser beam L₂ is applied to the carbon-contained monocrystalline substrate 11 along a next dividing groove 23 that is positioned adjacent along the Y-axis to the dividing groove 23 that has previously been irradiated with the laser beam L₂, removing the products 25 from the next dividing groove 23. Thereafter, the products 25 are removed from the carbon-contained monocrystalline substrate 11 along all of the dividing grooves 23 that extend along the X-axis. Then, the chuck table 14 is turned through approximately 90 degrees about the rotational axis thereof. Thereafter, the products 25 are similarly removed from the carbon-contained monocrystalline substrate 11 along all of the dividing grooves 23 that extend along the X-axis.

According to the present embodiment, inasmuch as the products 25 that may possibly bring about faults of the semiconductor device chips 27 are removed in the heating step S20, the yield of the semiconductor device chips 27 is rendered higher than if the products 25 were not removed.

In the heating step S20, the laser beam L₂ may not necessarily be defocused off the face side 11a of the carbon-contained monocrystalline substrate 11. Rather, the focused spot of the laser beam L₂ may be positioned on the face side 11a of the carbon-contained monocrystalline substrate 11 or may be positioned on the bottom surface or one of the side surfaces of each of the dividing grooves 23. If the focused spot of the laser beam L₂ has a diameter that is relatively large compared with the width of the dividing groove 23, the focused spot of the laser beam L₂ may be kept at a height that is closer to the opening edge of the dividing groove 23.

Further alternatively, the laser beam L₂ may be applied selectively to only one of the side surfaces of the dividing groove 23 by inclining the direction of travel of the laser beam L₂ from the beam condenser 18 with respect to the face side 11a. The laser beam L₂ may be applied obliquely to the face side 11a by using a liquid crystal on silicon-spatial light modulator (LCOS-SLM) with the condensing lens 18a having an optical axis perpendicular to the holding surface 14a, or by simply inclining the optical axis of the condensing lens 18a with respect to the holding surface 14a.

The laser beam L₂ may not necessarily be focused into a single focused spot. Instead, the laser beam L₂ may branch into a plurality of laser beams spaced along (i) the X-axis, (ii) the Y-axis, or (iii) a predetermined direction transverse to the X-axis and the Y-axis. The laser beam L₂ may be caused to branch by a diffractive optical element (DOE) or a LCOS-SLM, for example, placed on an optical path of the laser beam L₂. The focused spot of the laser beam L₂ has a cross-sectional shape that may not necessarily be circular and may be elliptical or rectangular, for example.

In a case where the carbon-contained monocrystalline substrate 11 is a silicon carbide substrate having a thickness of 350 μm and a diameter of 150 mm, an example of processing conditions in the processed-groove forming step S10 is given below. In the heating step S20, either the above processing conditions for the continuous wave or the above processing conditions for the pulsed wave may be employed.
Laser beam wavelength: 343 nm (i.e., third harmonic of the wavelength of 1030 nm)
Average power output: 6 W
Repetitive frequency: 10 kHz
Processing-feed speed: 80 mm/s
Number of passes: 36

According to the first embodiment, the heating step S20 is carried out after the processed-groove forming step S10. However, the processed-groove forming step S10 and the heating step S20 may be carried out concurrently. The processed-groove forming step S10 and the heating step S20 are carried out concurrently by use of, for example, a laser processing apparatus, not depicted, that includes the laser beam applying unit 6 (see FIG. 3A) and the laser beam applying unit 16 (see FIG. 4A). For processing the carbon-contained monocrystalline substrate 11 with the laser beams, the beam condenser 8 and the beam condenser 18 are spaced apart along the X-axis such that the focused spot of the laser beam L₁ will reach the carbon-contained monocrystalline substrate 11 earlier than the focused spot of the laser beam L₂, and then a chuck table, which corresponds to the chuck tables 4 and 14, with the carbon-contained monocrystalline substrate 11 held thereon is moved relatively to the beam condensers 8 and 18 along the X-axis.

For example, the heating step S20 can be carried out while at the same time the processed-groove forming step S10 is being carried out by moving the focused spots of the laser beams L₁ and L₂ in a manner to cause the focused spot of the laser beam L₂ to follow the focused spot of the laser beam L₁. In other words, the processed-groove forming step S10 and the heating step S20 can be carried out simultaneously, thereby reducing the period of time required to process the carbon-contained monocrystalline substrate 11 with the laser beams L₁ and L₂. When the processed-groove forming step S10 and the heating step S20 are carried out simultaneously, the number of passes is not limited to any particular numerical value and may be 2 or more.

Alternatively, while the focused spot of the laser beam L₁ and the focused spot of the laser beam L₂ are positioned at substantially the same location, the focused spots and the chuck table may be moved relatively to each other along the X-axis. In a case where the focused spot of the laser beam L₁ and the focused spot of the laser beam L₂ are positioned at substantially the same location, the products 25 produced by the laser beam L₁ on the first pass are removed by the laser beam L₂ on the second pass, for example.

Further, for example, providing the focused spot of the laser beam L₂ is larger in diameter than the focused spot of the laser beam L₁, then the products 25 produced by the laser beam L₁ on the first pass can be removed by the laser beam L₂ on the first pass if the center of the focused spot of the laser beam L₁ and the center of the focused spot of the laser beam L₂ are substantially in alignment with each other.

The laser beam applying unit 6 may be disposed above a chuck table and the laser beam applying unit 16 may be disposed below the chuck table. In this case, the chuck table has a holding member that is made of a material transparent to or transmissive of the laser beam L₂ and that has a substantially flat upper surface. The material of the holding member may be glass such as quartz glass or a single crystal substrate of zinc selenide (ZnSe), for example. The holding member has a plurality of suction holes defined in an outer circumferential portion thereof at substantially equal spaced intervals along circumferential directions of the holding member for transmitting therethrough a negative pressure for holding the workpiece unit 21 under suction on the holding member.

For processing the carbon-contained monocrystalline substrate 11 with the laser beams, the laser beam applying unit 6 applies the laser beam L₁ directly to the carbon-contained monocrystalline substrate 11 and the laser beam applying unit 16 applies the laser beam L₂ via the chuck table to the carbon-contained monocrystalline substrate 11. At this time, the focused spots of the laser beams L₁ and L₂ are moved in a manner to cause the focused spot of the laser beam L₂ to follow the focused spot of the laser beam L₁, for example.

Alternatively, while the focused spot of the laser beam L₁ and the focused spot of the laser beam L₂ are positioned at substantially the same location, the focused spots and the chuck table may be moved relatively to each other. Needless to say, in a case where the chuck table has the holding member referred to above, the laser beam applying unit 16 may be disposed above a chuck table and the laser beam applying unit 6 may be disposed below the chuck table.

### Second Embodiment

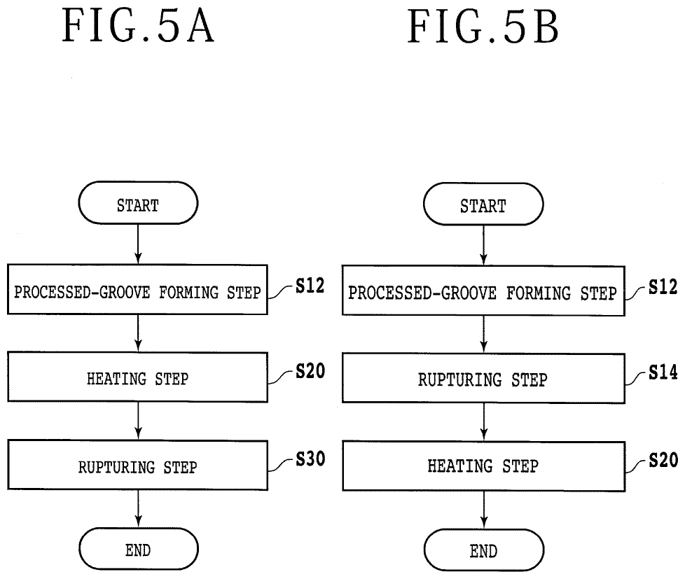

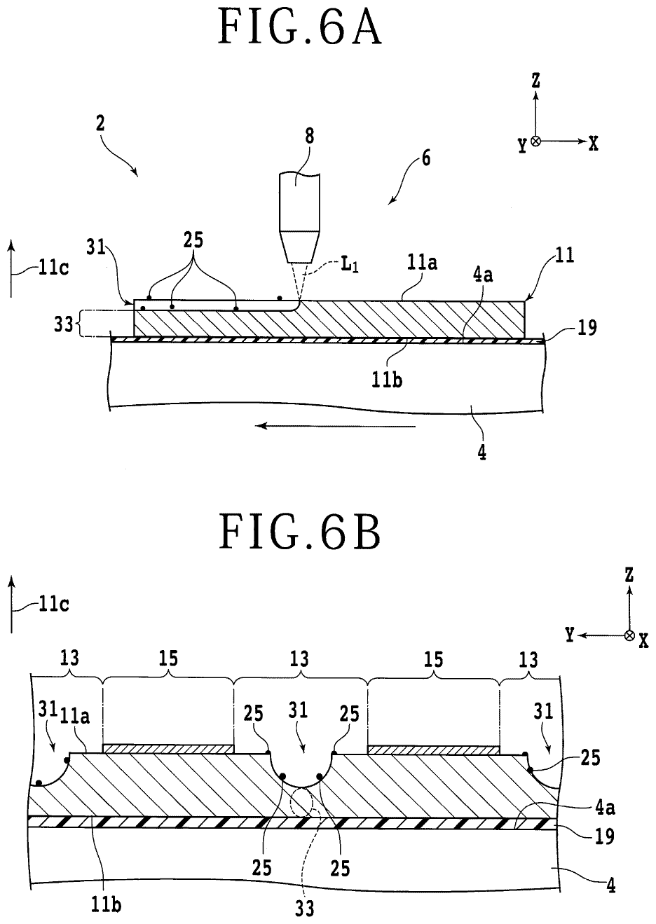

A method of processing a carbon-contained monocrystalline substrate according to a second embodiment of the present invention will be described below with reference to FIGS. 5A through 8B. FIG. 5A is a flowchart of a processing sequence of the substrate processing method according to the second embodiment. According to the second embodiment, after a half-cut groove, i.e., a processed groove, 31 has been formed in the carbon-contained monocrystalline substrate 11 along each projected dicing line 13 by the laser beam L₁ in a processed-groove forming step S12 (see FIG. 6A), the products 25 are removed by the laser beam L₂ in the heating step S20.

Then, in a rupturing step S30 after the heating step S20, an external force is applied to a residual region 33 (see FIG. 6A) of the carbon-contained monocrystalline substrate 11 that is positioned between the half-cut groove 31 of the carbon-contained monocrystalline substrate 11 and the reverse side 11b, thereby rupturing the carbon-contained monocrystalline substrate 11 along the projected dicing line 13. FIG. 5B is a flowchart of a processing sequence of a modification of the substrate processing method according to the second embodiment. According to the modification, after a half-cut groove, i.e., a processed groove, 31 has been formed in the carbon-contained monocrystalline substrate 11 along each projected dicing line 13 by the laser beam L₁ in the processed-groove forming step S12, a rupturing step S14 is carried out before the heating step S20, and then the heating step S20 is carried out using the laser beam L₂ after the rupturing step S14.

The flowchart of FIG. 5A will first be described below. FIG. 6A illustrates in fragmentary side elevation, partly in cross section, a manner in which the processed-groove forming step S12 of the substrate processing method according to the second embodiment is carried out. In the processed-groove forming step S12, a half-cut groove 31 having a depth not large enough to sever the carbon-contained monocrystalline substrate 11 is formed in the carbon-contained monocrystalline substrate 11 along each projected dicing line 13. The half-cut groove 31 referred to herein has a depth from the face side 11a to a point in the carbon-contained monocrystalline substrate 11 that is short of the reverse side 11b, and does not necessarily have a depth exactly half the distance between the face side 11a and the reverse side 11b along a thicknesswise direction 11c of the carbon-contained monocrystalline substrate 11.

According to the second embodiment, the processed-groove forming step S12 is carried out in substantially the same manner as with the processed-groove forming step S10 described above by the laser processing apparatus 2. An example of processing conditions in the processed-groove forming step S12 is given below. The example represents processing conditions for processing a diamond substrate having a thickness of 500 μm and a diameter of 5 mm as the carbon-contained monocrystalline substrate 11.
Laser beam wavelength: 1030 nm
Average power output: 80 W
Repetitive frequency: 2000 KHz
Processing-feed speed: 100 mm/s
Number of passes: 45

If the number of passes is 2 or more, then the focused spot of the laser beam L₁ may be brought closer stepwise from the face side 11a to the reverse side 11b depending on the number of passes. In other words, the focused spot of the laser beam L₁ may be closest to the face side 11a on the first of the passes and may be closest to the reverse side 11b on the last of the passes.

FIG. 6B illustrates half-cut grooves 31 formed in the carbon-contained monocrystalline substrate 11 according to the second embodiment, in a cross section taken along a plane extending through the carbon-contained monocrystalline substrate 11 across the longitudinal directions of the half-cut grooves 31. As a result of the processed-groove forming step S12, products 25 are deposited within the half-cut grooves 31, i.e., on bottom and side surfaces thereof and on opening edges of the half-cut grooves 31. According to the present embodiment, after the processed-groove forming step S12, the products 25 are removed from the carbon-contained monocrystalline substrate 11 by the laser processing apparatus 12 in the heating step S20.

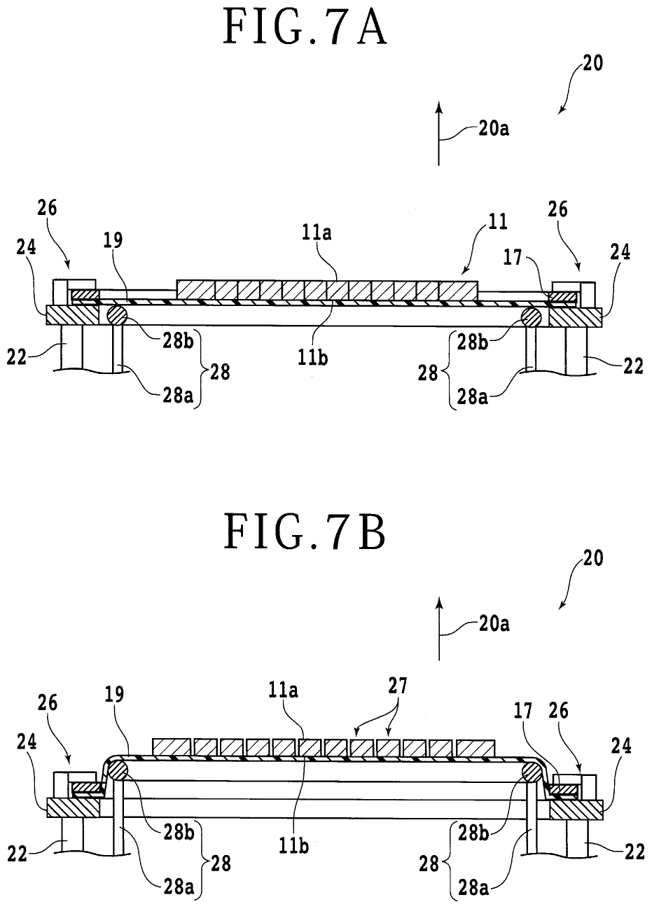

According to the second embodiment, although not illustrated, the heating step S20 is carried out in the same manner as with the heating step S20 described above with reference to FIGS. 4A and 4B. Processing conditions may be the same as those described above for the laser beam of a pulsed wave or a continuous wave. After the products 25 have been removed in the heating step S20, an external force is applied by an expanding apparatus 20 (see FIG. 7A) to the residual region 33 of the carbon-contained monocrystalline substrate 11 that underlies the half-cut groove 31 in the thicknesswise direction 11c, thereby rupturing the carbon-contained monocrystalline substrate 11 in the rupturing step S30.

FIG. 7A illustrates the expanding apparatus 20 in side elevation, partly in cross section. As illustrated in FIG. 7A, the expanding apparatus 20 has a plurality of legs 22 to stand on a floor. A ring-shaped support 24 is fixed to respective upper ends of the legs 22. A plurality of clamp units 26 are provided on an upper surface of an outer circumferential portion of the support 24 at respective different positions spaced at substantially constant intervals circumferentially around the support 24. The expanding apparatus 20 also includes a plurality of thrusting-up units 28 disposed radially inwardly of the legs 22, for lifting the dicing tape 19 of the workpiece unit 21 set on the expanding apparatus 20.

The thrusting-up units 28 have respective legs 28a that can be lifted along a heightwise direction 20a of the expanding apparatus 20 and lowered in an opposite direction thereof. Cylindrical rollers 28b are rotatably mounted on respective upper ends of the legs 28a. In FIG. 7A, the rollers 28b have their upper ends illustrated as being at substantially the same height as the upper surface of the support 24. FIG. 7B illustrates a manner in which the rupturing step S30 is carried out in side elevation, partly in cross section.

In the rupturing step S30, as illustrated in FIG. 7A, the workpiece unit 21 is placed on the expanding apparatus 20 with the face side 11a of the carbon-contained monocrystalline substrate 11 exposed upwardly, and the annular frame 17 is secured by the clamp units 26. At this time, the annular frame 17 is supported on the upper surface of the support 24, and the rollers 28b have their respective outer circumferential side surfaces held in contact with an area of a lower surface of the dicing tape 19 that lies between an outer circumferential edge of the carbon-contained monocrystalline substrate 11 and an inner circumferential edge of the annular frame 17.

Then, the legs 28a of the thrusting-up units 28 are lifted to position the rollers 28b at a predetermined height higher than the support 24, thereby expanding the dicing tape 19 radially. Since the carbon-contained monocrystalline substrate 11 undergoes tensile stresses directed radially outwardly from the center of the dicing tape 19, the carbon-contained monocrystalline substrate 11 is ruptured at the residual regions 33 along the projected dicing lines 13 that are lower in mechanical strength than the other regions of the carbon-contained monocrystalline substrate 11. As a result, the carbon-contained monocrystalline substrate 11 is divided into a plurality of semiconductor device chips 27. According to the second embodiment, inasmuch as the products 25 that may possibly bring about faults of the semiconductor device chips 27 are removed in the heating step S20, the yield of the semiconductor device chips 27 is rendered higher than if the products 25 were not removed.

The flowchart of FIG. 5B will next be described below. According to the modification illustrated in FIG. 5B, after half-cut grooves 31 have been formed in the carbon-contained monocrystalline substrate 11 in the processed-groove forming step S12, the rupturing step S14 is carried out by the expanding apparatus 20, and then the heating step S20 is carried out to remove the products 25 by applying the laser beam L₂ to gaps between the semiconductor device chips 27.

The distance between adjacent two of the semiconductor device chips 27 after the rupturing step S14 is larger than the width of each of the half-cut grooves 31. In the heating step S20, therefore, after the laser beam L₂ has been applied to one widthwise side of each projected dicing line 13, the laser beam L₂ may be applied to the other widthwise side of the projected dicing line 13.

In a case where the carbon-contained monocrystalline substrate 11 is a silicon carbide substrate having a thickness of 350 μm and a diameter of 150 mm, an example of processing conditions in the processed-groove forming step S12 is given below.
Laser beam wavelength: 343 nm (i.e., third harmonic of the wavelength of 1030 nm)
Average power output: 6 W
Repetitive frequency: 10 kHz
Processing-feed speed: 80 mm/s
Number of passes: 18

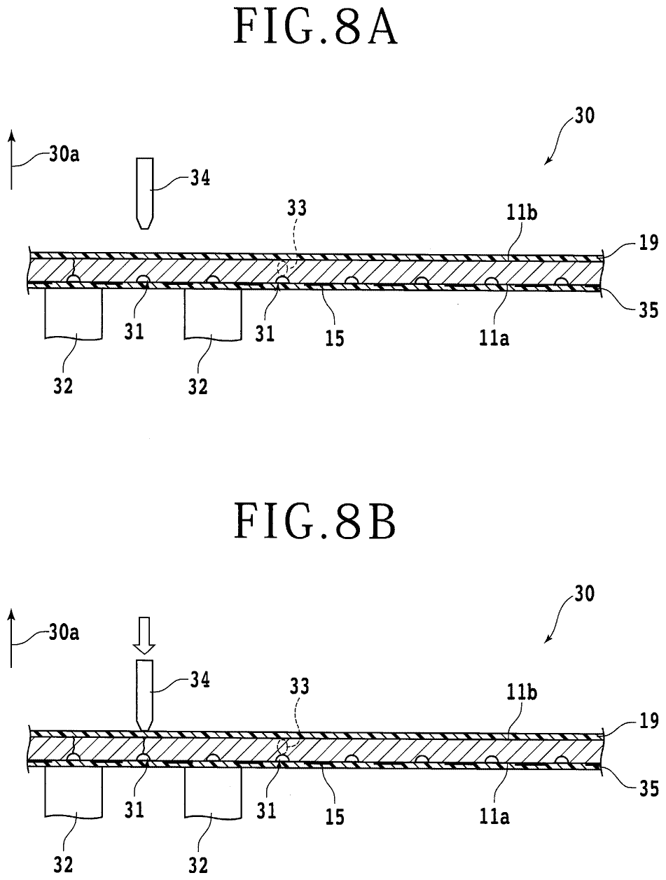

In the heating step S20 after the processed-groove forming step S12, either the above processing conditions for the continuous wave or the above processing conditions for the pulsed wave may be employed. According to a modification of the rupturing steps S30 and S14, a breaking apparatus 30 (see FIG. 8A) may be employed instead of the expanding apparatus 20.

FIG. 8A illustrates the breaking apparatus 30 in fragmentary side elevation, partly in cross section. As illustrated in FIG. 8A, the breaking apparatus 30 includes a pair of supporting blades 32 each having an upper end having a substantially flat surface and a pressing blade 34 that is disposed between, as viewed in plan, and above the supporting blades 32 and that is movable along a heightwise direction 30a of the breaking apparatus 30.

The pressing blade 34 has a lower end that is pointed downwardly unlike upper ends of the supporting blades 32. The lower end of the pressing blade 34 may lie substantially parallel to the upper ends of the supporting blades 32 or may be inclined in such a manner as to be progressively spaced from the upper ends of the supporting blades 32 along a direction away from the viewer of FIG. 8A. A microscope camera unit, not depicted, for capturing an image of the carbon-contained monocrystalline substrate 11 is disposed between the supporting blades 32 and below the upper ends of the supporting blades 32.

Before the rupturing steps S30 and S14 are carried out by the breaking apparatus 30, the face side 11a of the carbon-contained monocrystalline substrate 11 is covered with a protective tape 35 of resin in order to reduce damage to the devices 15 on the carbon-contained monocrystalline substrate 11. Then, the workpiece unit 21 is supported on the supporting blades 32 such that the face side 11a faces downwardly, i.e., the reverse side 11b faces upwardly. Then, the microscope camera unit captures an image of the face side 11a.

Based on the image captured by the microscope camera unit, the positions of the supporting blades 32 and the pressing blade 34 with respect to the half-cut groove 31 that is positioned between the supporting blades 32 are adjusted to place the pressing blade 34 immediately above the residual region 33 above the half-cut groove 31. Then, as illustrated in FIG. 8B, the pressing blade 34 is lowered to apply a downward force to the carbon-contained monocrystalline substrate 11 through the dicing tape 19.

FIG. 8B illustrates in fragmentary side elevation, partly in cross section, a manner in which the modification of the rupturing steps S30 and S14 is carried out by the breaking apparatus 30. As illustrated in FIG. 8B, when the downward force is applied by the pressing blade 34 to the carbon-contained monocrystalline substrate 11 through the dicing tape 19, a bending stress is developed in the carbon-contained monocrystalline substrate 11, giving rise to cracks from the bottom of the half-cut groove 31 to the reverse side 11b, thereby rupturing the residual region 33. The carbon-contained monocrystalline substrate 11 is now divided along the projected dicing line 13. By similarly rupturing the residual regions 33 along all of the projected dicing lines 13 on the carbon-contained monocrystalline substrate 11, the carbon-contained monocrystalline substrate 11 is divided into a plurality of semiconductor device chips 27. After the rupturing steps S30 and S14, the protective tape 35 is peeled off from the face side 11a.

According to an alternative, the rupturing steps S30 and S14 may be carried out by a breaking apparatus that has a substantially flat table, not depicted, and a pressing roller, not depicted, that is disposed over the table and that has a longitudinal portion longer than the diameter of the carbon-contained monocrystalline substrate 11, rather than the supporting blades 32 and the pressing blade 34. In the rupturing steps S30 and S14, the workpiece unit 21 is placed on the table with the dicing tape 19 exposed upwardly and the protective tape 35 held in contact with the table. Then, the pressing roller is pressed against the dicing tape 19 and rolled over to apply a downward force to the carbon-contained monocrystalline substrate 11 through the dicing tape 19.

The downward force that is applied by the pressing roller to the carbon-contained monocrystalline substrate 11 through the dicing tape 19 develops a bending stress in the carbon-contained monocrystalline substrate 11, giving rise to cracks from the bottom of the half-cut groove 31 to the reverse side 11b, thereby rupturing the residual region 33. By rupturing the residual regions 33 along all of the projected dicing lines 13 on the carbon-contained monocrystalline substrate 11, the carbon-contained monocrystalline substrate 11 is divided into a plurality of semiconductor device chips 27.

After the rupturing step S30 has been carried out by the breaking apparatus 30 or after the rupturing step S14 and the heating step S20 have been carried out by the breaking apparatus 30, the distances between the semiconductor device chips 27 may be increased by the expanding apparatus 20 to allow the semiconductor device chips 27 to be picked up easily.

### Third Embodiment

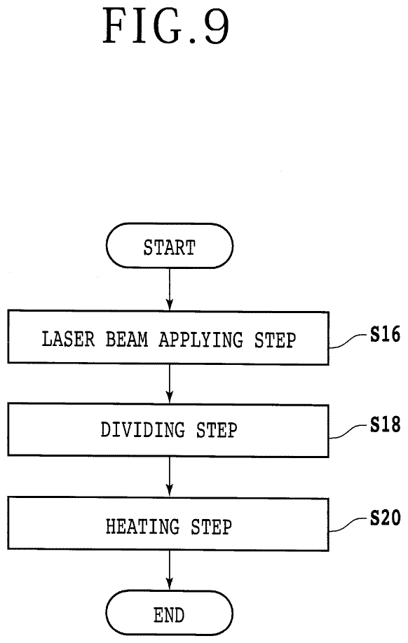

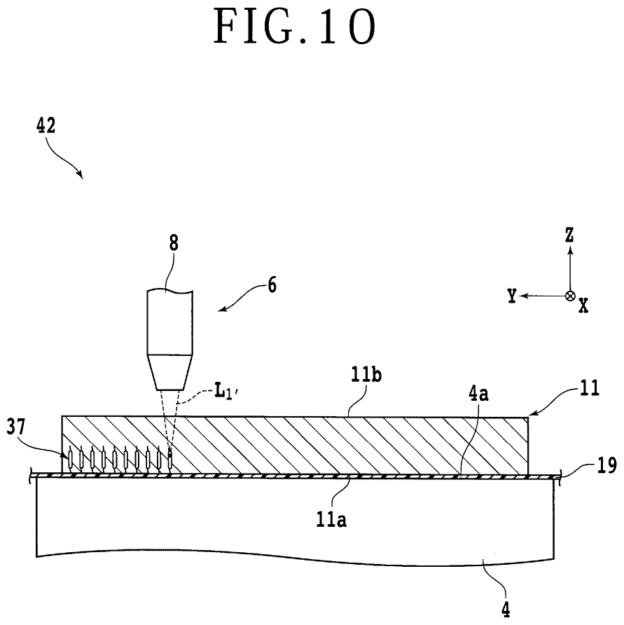

A method of processing a carbon-contained monocrystalline substrate according to a third embodiment of the present invention will be described below with reference to FIGS. 9 through 12. FIG. 9 is a flowchart of a processing sequence of the substrate processing method according to the third embodiment. According to the third embodiment, a laser beam applying step S16, a dividing step S18, and the heating step S20 are successively carried out in the order named. The laser beam applying step S16 is carried out by a laser processing apparatus 42 (see FIG. 10) that is substantially the same as the laser processing apparatus 2 described above. As with the laser processing apparatus 2, the laser processing apparatus 42 includes a chuck table 4 and a laser beam applying unit 6 having a beam condenser 8.

The laser beam applying unit 6 of the laser processing apparatus 42 applies a pulsed laser beam L_{1′}, i.e., a first laser beam, having a wavelength transmittable through the carbon-contained monocrystalline substrate 11 to the carbon-contained monocrystalline substrate 11 along each projected dicing line 13, forming fragile regions 37 that are lower in mechanical strength than non-irradiated regions of the carbon-contained monocrystalline substrate 11 to which the pulsed laser beam Ly is not applied, within the carbon-contained monocrystalline substrate 11, as illustrated in FIG. 10.

Specifically, the laser beam L_{1′} has a wavelength of 1030 nm or 1064 nm and is transmittable through both diamond substrates and silicon carbide substrates. The transmittance of the laser beam Ly with respect to the carbon-contained monocrystalline substrate 11 may not necessarily be 100%. For example, the transmittance of the laser beam Ly with respect to a diamond substrate is approximately 70%, whereas the transmittance of the laser beam L_{1′} with respect to a silicon carbide substrate is approximately 15%.

In the case where the laser beam L_{1′}, has a wavelength of 1030 nm, a Yb: YAG crystal is used as the laser medium, for example. In the case where the laser beam L_{1′} has a wavelength of 1064 nm, an Nd: YAG crystal is used as the laser medium, for example.

FIG. 10 illustrates in side elevation, partly in cross section, a manner in which the laser beam applying step S16 of the substrate processing method according to the third embodiment is carried out. In FIG. 10, the devices 15 on the carbon-contained monocrystalline substrate 11 are omitted from illustration for illustrative purposes. In the laser beam applying step S16, the dicing tape 19 is affixed to the face side 11a of the carbon-contained monocrystalline substrate 11 and the surface of the annular frame 17. The holding surface 4a of the chuck table 4 then holds under suction the face side 11a of the carbon-contained monocrystalline substrate 11 with the reverse side 11b exposed upwardly. Thereafter, based on an image of the face side 11a captured by a microscope camera unit, the orientation of the chuck table 4 is adjusted to make one of the projected dicing lines 13 substantially parallel to the X-axis.

Then, while a focused spot of laser beam Ly is being kept at a predetermined height within the carbon-contained monocrystalline substrate 11, the beam condenser 8 and the chuck table 4 are moved relatively to each other along the X-axis. For example, the beam condenser 8 is held at rest, and the chuck table 4 is moved along the X-axis at a predetermined processing-feed speed.

In this manner, the laser beam L_{1′} emitted from the beam condenser 8 is applied to the carbon-contained monocrystalline substrate 11 along the projected dicing line 13, forming a fragile region 37 within the carbon-contained monocrystalline substrate 11. The fragile region 37 refers to a region that is different in crystallinity than non-irradiated regions of the carbon-contained monocrystalline substrate 11 to which the pulsed laser beam L_{1′} is not applied, and includes a modified region left blank in FIG. 10 and cracks developed from the modified region toward the face side 11a and the reverse side 11b. In the laser beam applying step S16, products 25 referred to above are produced in the vicinity of the fragile region 37.

An example of processing conditions in the laser beam applying step S16 is given below. The example represents processing conditions for processing a diamond substrate having a thickness of 500 μm and a diameter of 5 mm as the carbon-contained monocrystalline substrate 11.
Laser beam wavelength: 1030 nm or 1064 nm
Average power output: 2 W
Repetitive frequency: 50 kHz
Processing-feed speed: 400 mm/s
Number of passes: 8

In the laser beam applying step S16, a processing method called stealth dicing (SD) is used to apply the laser beam L_{1′} that has an average power output lower than the laser beam L₁ used in the processed-groove forming step S10 according to the first and second embodiments, bringing about multiphoton absorption, not ablation, in the vicinity of the focused spot of the laser beam L_{1′}, thereby forming the fragile region 37. If the number of passes is 2 or more, then the focused spot of the laser beam L_{1′} may be brought closer stepwise from the face side 11a to the reverse side 11b depending on the number of passes. In other words, the focused spot of the laser beam L_{1′} may be closest to the face side 11a on the first of the passes and may be closest to the reverse side 11b on the last of the passes.

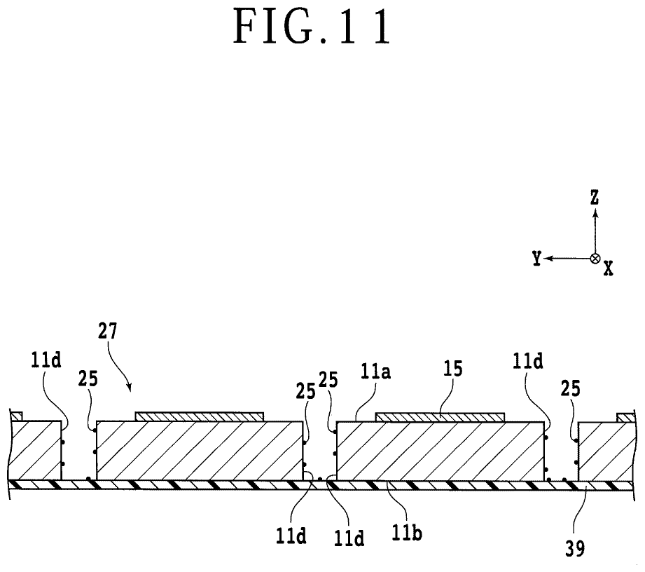

After the laser beam applying step S16, a circular tape 39 (see FIG. 11) is affixed to the reverse side 11b and the surface of the annular frame 17, and the dicing tape 19 is peeled off from the face side 11a. The tape 39 is plastically deformable by being stretched radially outwardly by the expanding apparatus 20. Thereafter, the dividing step S18 is carried out by the expanding apparatus 20. In the dividing step S18, an external force is applied to the carbon-contained monocrystalline substrate 11 to divide the carbon-contained monocrystalline substrate 11 along each projected dicing line 13 into a plurality of semiconductor device chips 27, as illustrated in FIG. 11.

FIG. 11 illustrates in fragmentary side elevation the carbon-contained monocrystalline substrate 11 after the dividing step S18 of the substrate processing method according to the third embodiment. In the dividing step S18, the carbon-contained monocrystalline substrate 11 may be divided by the breaking apparatus 30 including the pressing blade 34 or the pressing roller, rather than the expanding apparatus 20, and thereafter the distances between the semiconductor device chips 27 may be increased by the expanding apparatus 20.

In case the dicing tape 19 is plastically deformable, the tape 39 may not be affixed to the reverse side 11b, and the dicing tape 19 that remains unpeeled off may be expanded by being stretched by the expanding apparatus 20. Alternatively, while the dicing tape 19 is being affixed to the reverse side 11b, the laser beam applying step S16 may be carried out, and then the dicing tape 19 may be expanded by the expanding apparatus 20 in the dividing step S18.

As illustrated in FIG. 11, the products 25 produced in the laser beam applying step S16 remain on severance surfaces 11d of the carbon-contained monocrystalline substrate 11 that have been exposed in the dividing step S18. After the dividing step S18, the heating step S20 is carried out by the laser processing apparatus 12.

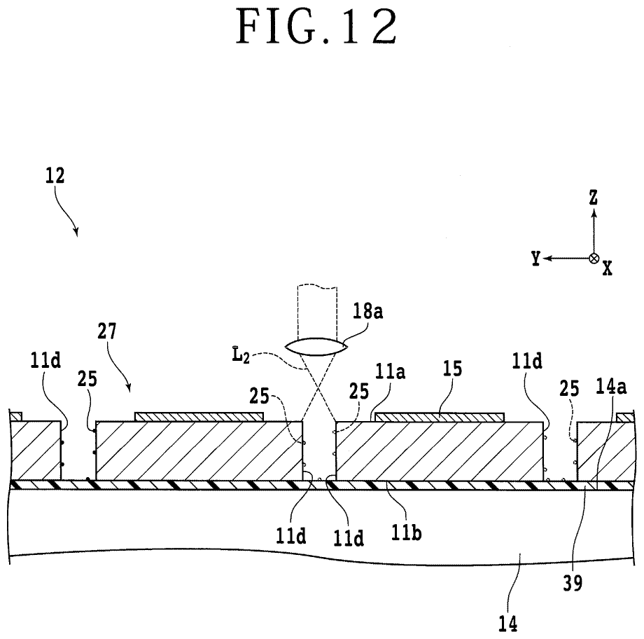

FIG. 12 illustrates in side elevation, partly in cross section, a manner in which the heating step S20 of the substrate processing method according to the third embodiment is carried out. In the heating step S20, the laser beam L₂ is applied to at least the severance surfaces 11d, causing the products 25 on the severance surfaces 11d to react with oxygen to vaporize the products 25. In this manner, the products 25 are removed from the severance surfaces 11d. In the heating step S20, part of the laser beam L₂ may be applied to the face side 11a. According to the third embodiment, the heating step S20 is carried out in the same manner as with the heating step S20 described above with reference to FIGS. 4A and 4B. Processing conditions may be the same as those described above for the laser beam of a pulsed wave or a continuous wave.

According to the third embodiment, inasmuch as the products 25 that may possibly bring about faults of the semiconductor device chips 27 are removed in the heating step S20, the yield of the semiconductor device chips 27 is rendered higher than if the products 25 were not removed.

In a case where the carbon-contained monocrystalline substrate 11 is a silicon carbide substrate having a thickness of 350 μm and a diameter of 150 mm, an example of processing conditions in the laser beam applying step S16 is given below.
Laser beam wavelength: 1030 nm or 1064 nm
Average power output: 1 W
Repetitive frequency: 50 kHz
Processing-feed speed: 600 mm/s
Number of passes: 2

In the heating step S20 after the laser beam applying step S16, either the above processing conditions for the continuous wave or the above processing conditions for the pulsed wave may be employed.

### Fourth Embodiment

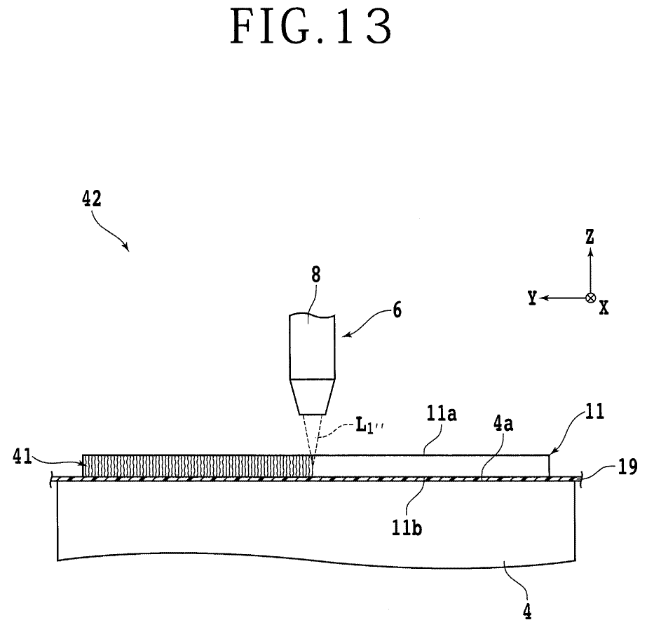

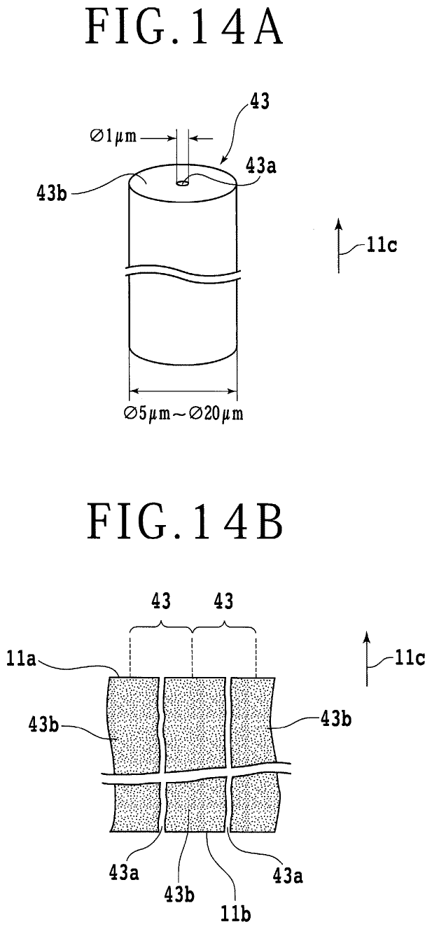

A method of processing a carbon-contained monocrystalline substrate according to a fourth embodiment of the present invention will be described below with reference to FIGS. 13, 14A, and 14B. According to the fourth embodiment, the substrate processing method is performed according to the processing sequence illustrated in FIG. 9. According to the fourth embodiment, in the laser beam applying step S16, a fragile region 41 that is different from the fragile region 37 illustrated in FIG. 10 is formed in the carbon-contained monocrystalline substrate 11 as illustrated in FIG. 13. Though the substrate processing method according to the fourth embodiment is different from the substrate processing method according to the third embodiment as to the laser beam applying step S16, the substrate processing method according to the fourth embodiment includes the dividing step S18 and the heating step S20 that are identical to those of the substrate processing method according to the third embodiment. Therefore, the substrate processing method according to the fourth embodiment will be described below mainly with regard to the laser beam applying step S16.

According to the fourth embodiment, the laser beam applying step S16 is carried out by the laser processing apparatus 42 described above with reference to FIG. 10. FIG. 13 illustrates in side elevation, partly in cross section, a manner in which the laser beam applying step S16 of the substrate processing method according to the fourth embodiment is carried out. In FIG. 13, the devices 15 on the carbon-contained monocrystalline substrate 11 are omitted from illustration for illustrative purposes, and the carbon-contained monocrystalline substrate 11 is not illustrated as hatched in its cross section. In the laser beam applying step S16 according to the fourth embodiment, the reverse side 11b of the carbon-contained monocrystalline substrate 11 is held under suction on the holding surface 4a with the dicing tape 19 interposed therebetween, with the face side 11a exposed upwardly, unlike the carbon-contained monocrystalline substrate 11 in the laser beam applying step S16 according to the third embodiment illustrated in FIG. 10.

In the laser beam applying step S16, the laser beam applying unit 6 of the laser processing apparatus 42 applies a pulsed laser beam L_{1″}, i.e., a first laser beam, having a wavelength transmittable through the carbon-contained monocrystalline substrate 11 to the carbon-contained monocrystalline substrate 11 along each projected dicing line 13, forming a fragile region 41 that is low in mechanical strength within the carbon-contained monocrystalline substrate 11. An example of processing conditions in the laser beam applying step S16 is given below. The example represents processing conditions for processing a diamond substrate having a thickness of 500 μm and a diameter of 5 mm as the carbon-contained monocrystalline substrate 11.
Laser beam wavelength: 1064 nm
Average power output: 4 W
Repetitive frequency: 10 kHz
Processing-feed speed: 400 mm/s
Number of passes: 7

If the number of passes is 2 or more, then a focused spot of the laser beam L_{1″} may be brought closer stepwise from the face side 11a to the reverse side 11b depending on the number of passes. In other words, the focused spot of the laser beam L_{1″} may be closest to the face side 11a on the first of the passes and may be closest to the reverse side 11b on the last of the passes. The fragile region 41 refers to a region that is different in crystallinity than non-irradiated regions of the carbon-contained monocrystalline substrate 11 to which the laser beam L_{1″} is not applied, and is called a shield tunnel region. The fragile region 41 has a plurality of shield tunnels 43 (see FIG. 14A).

FIG. 14A illustrates in perspective a structure of a shield tunnel 43. In FIG. 14A, part of the carbon-contained monocrystalline substrate 11 in its thicknesswise direction 11c is omitted from illustration. The shield tunnel 43 has a thin hole 43a defined axially therethrough along the thicknesswise direction 11c. The thin hole 43a is represented by a substantially tubular thin elongate space having a diameter of approximately 1 μm, and extends from the face side 11a to the reverse side 11b through the carbon-contained monocrystalline substrate 11, for example.

If the number of passes is 2 or more, then the carbon-contained monocrystalline substrate 11 is processed with the laser beam L_{1″} while its focused spot is brought closer stepwise from the face side 11a to the reverse side 11b. In this case, even if the repetitive frequency and the processing-feed speed are constant, the thin holes 43a may not completely overlap with each other in the thicknesswise direction 11c of the carbon-contained monocrystalline substrate 11.

The shield tunnel 43 has a modified region 43b formed in surrounding relation to a side surface of the thin hole 43a. The modified region 43b is a substantially cylindrical region having a diameter ranging approximately from 5 μm to 20 μm, for example. The modified region 43b refers to a region where part of the carbon-contained monocrystalline substrate 11 has its crystal structure changed due to energy received from the laser beam L_{1″}. The modified region 43b may be paraphrased as an amorphous region or a polycrystalline region, for example.

In the laser beam applying step S16, a processing method called laser enhanced ablation filling (LEAF) is used to apply the laser beam L_{1″} that has an average power output higher than that of the laser beam Ly used in the laser beam applying step S16 according to the third embodiment, forming the modified region 43b as well as the thin hole 43a by way of ablation.

FIG. 14B illustrates in fragmentary cross-section the carbon-contained monocrystalline substrate 11 having a plurality of shield tunnels 43 formed therein along one of the projected dicing lines 13. In FIG. 14B, part of the carbon-contained monocrystalline substrate 11 in its thicknesswise direction 11c is omitted from illustration. As illustrated in FIG. 14B, adjacent two of the shield tunnels 43 that are disposed adjacent to each other along the projected dicing line 13 have their modified regions 43b joined to each other. However, the two modified regions 43b may be spaced from each other. That is, those adjacent two of the shield tunnels 43 that are disposed adjacent to each other along the projected dicing line 13 may be spaced from each other with a monocrystalline region remaining therebetween.

After the laser beam applying step S16, the dividing step S18 is carried out by the expanding apparatus 20. In the dividing step S18, the carbon-contained monocrystalline substrate 11 may be divided by the breaking apparatus 30 including the pressing blade 34 or the pressing roller, rather than the expanding apparatus 20, and thereafter, the distances between the semiconductor device chips 27 may be increased by the expanding apparatus 20. Products 25 produced in the laser beam applying step S16 remain on the severance surfaces 11d of the carbon-contained monocrystalline substrate 11 that have been exposed in the dividing step S18. After the dividing step S18, the heating step S20 is carried out by the laser processing apparatus 12 described above (see FIG. 12).

In the heating step S20, the laser beam L₂ is applied to at least the severance surfaces 11d, causing the products 25 on the severance surfaces 11d to react with oxygen to vaporize the products 25. In this manner, the products 25 are removed from the severance surfaces 11d. According to the fourth embodiment, the heating step S20 is carried out in the same manner as with the heating step S20 described above with reference to FIGS. 4A and 4B. Processing conditions may be the same as those described above for the laser beam of a pulsed wave or a continuous wave.

According to the fourth embodiment, inasmuch as the products 25 that may possibly bring about faults of the semiconductor device chips 27 are removed in the heating step S20, the yield of the semiconductor device chips 27 is rendered higher than if the products 25 were not removed.

In a case where the carbon-contained monocrystalline substrate 11 is a silicon carbide substrate having a thickness of 350 μm and a diameter of 150 mm, an example of processing conditions in the laser beam applying step S16 is given below.
Laser beam wavelength: 1064 nm
Average power output: 4 W
Repetitive frequency: 10 kHz
Processing-feed speed: 400 mm/s
Number of passes: 7

In the heating step S20 after the laser beam applying step S16, either the above processing conditions for the continuous wave or the above processing conditions for the pulsed wave may be employed. The structural and methodical details according to the above embodiments may be changed or modified as appropriate without departing from the scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of processing a carbon-contained monocrystalline substrate that contains carbon as a main component of a single crystal, comprising:
a processed-groove forming step of forming a processed groove in the carbon-contained monocrystalline substrate by applying a first laser beam having a wavelength absorbable by the carbon-contained monocrystalline substrate to the carbon-contained monocrystalline substrate along a projected dicing line established on one surface of the carbon-contained monocrystalline substrate; and
a heating step of causing products that contain carbon, that have a structure different from that of a material of the carbon-contained monocrystalline substrate, that are produced in the processed-groove forming step, and that are positioned at least within the processed groove to react with oxygen to vaporize the products, thereby removing the products, by applying a second laser beam having a wavelength transmittable through the carbon-contained monocrystalline substrate and absorbable by the products to the carbon-contained monocrystalline substrate along the processed groove.

2. The method of processing a carbon-contained monocrystalline substrate according to claim 1, wherein the processed-groove forming step includes severing the carbon-contained monocrystalline substrate by forming the processed groove that extends through the carbon-contained monocrystalline substrate from the one surface thereof to another surface thereof that is opposite the one surface.

3. The method of processing a carbon-contained monocrystalline substrate according to claim 1, wherein the processed-groove forming step includes forming the processed grove that has a depth from the one surface of the carbon-contained monocrystalline substrate to a point therein that is short of another surface thereof that is opposite the one surface, without severing the carbon-contained monocrystalline substrate,
the method further comprising:
before or after the heating step, a rupturing step of rupturing the carbon-contained monocrystalline substrate by applying an external force to a residual region of the carbon-contained monocrystalline substrate that underlies the processed groove in a thicknesswise direction of the carbon-contained monocrystalline substrate.

4. A method of processing a carbon-contained monocrystalline substrate that contains carbon as a main component of a single crystal, comprising:
a laser beam applying step of applying a pulsed first laser beam having a wavelength transmittable through the carbon-contained monocrystalline substrate to the carbon-contained monocrystalline substrate along a projected dicing line established thereon, thereby forming a fragile region that is lower in mechanical strength than a non-irradiated region of the carbon-contained monocrystalline substrate to which the pulsed first laser beam is not applied, within the carbon-contained monocrystalline substrate;
after the laser beam applying step, a dividing step of dividing the carbon-contained monocrystalline substrate along the projected dicing line by applying an external force to the carbon-contained monocrystalline substrate; and
after the dividing step, a heating step of causing products that contain carbon, that have a structure different from that of a material of the carbon-contained monocrystalline substrate, and that are produced in the laser beam applying step to react with oxygen to vaporize the products, thereby removing the products, by applying a second laser beam having a wavelength transmittable through the carbon-contained monocrystalline substrate and absorbable by the products to at least severance surfaces of the carbon-contained monocrystalline substrate that have been exposed in the dividing step.

5. The method of processing a carbon-contained monocrystalline substrate according to claim 1, wherein the wavelength of the second laser beam applied to the carbon-contained monocrystalline substrate in the heating step is in a range of 9.0 μm to 11.0 μm.

6. The method of processing a carbon-contained monocrystalline substrate according to claim 1, wherein the carbon-contained monocrystalline substrate is a diamond substrate.

7. The method of processing a carbon-contained monocrystalline substrate according to claim 1, wherein the carbon-contained monocrystalline substrate is a silicon carbide substrate.

8. The method of processing a carbon-contained monocrystalline substrate according to claim 1, wherein the products contain graphite or amorphous carbon.

9. The method of processing a carbon-contained monocrystalline substrate according to claim 4, wherein the wavelength of the second laser beam applied to the carbon-contained monocrystalline substrate in the heating step is in a range of 9.0 μm to 11.0 μm.

10. The method of processing a carbon-contained monocrystalline substrate according to claim 4, wherein the carbon-contained monocrystalline substrate is a diamond substrate.

11. The method of processing a carbon-contained monocrystalline substrate according to claim 4, wherein the carbon-contained monocrystalline substrate is a silicon carbide substrate.

12. The method of processing a carbon-contained monocrystalline substrate according to claim 4, wherein the products contain graphite or amorphous carbon.
